(19) United States
(12) Patent Application Publication
(10) Pub. No.: US 2026/0143571 A1
(43) Pub. Date: May 21, 2026

(54) HIGHLY COMPATIBLE POWER CONTROLLER

(71) Applicant: Xiamen PVTECH Co., Ltd., Xiamen (CN)

(72) Inventors: RONGTU LIU, Xiamen (CN); FUXING LU, Xiamen (CN); CHUNMING LIU, Xiamen (CN)

(21) Appl. No.: 19/372,297

(22) Filed: Oct. 29, 2025

Related U.S. Application Data
(63) Continuation-in-part of application No. 19/012,882, filed on Jan. 8, 2025.

(30) Foreign Application Priority Data
Nov. 15, 2024 (CN) 202411639157.9
Aug. 20, 2025 (CN) 202511166721.4

(51) Int. Cl. H05B 45/56; H03K 3/037; H05B 45/30; H03K 19/21

(52) U.S. Cl. CPC H05B 45/56; H03K 3/037; H05B 45/30; H03K 19/21

(57) ABSTRACT

A highly compatible power controller includes a signal identification element with a high-frequency signal recognizer, a switch driver, and a switch element. The high-frequency signal recognizer includes a signal input terminal, signal adjuster, first timer, second timer, AND gate, and latch. The input terminal receives a first input signal, forwarded to the signal adjuster, which generates an adjusted signal for the first timer. The first timer detects the adjusted signal's frequency within a preset detection window, producing a first detection signal sent to the AND gate. Simultaneously, the second timer generates a second detection signal based on the first input signal and a voltage startup threshold, also transmitted to the AND gate. The AND gate outputs a first logic signal to the latch, which then controls the switch driver to turn the switch element on or off.

### TECHNICAL FIELD

The present invention relates to a controller, in particular to a highly compatible power controller.

### BACKGROUND

Ballast-compatible lighting devices have been widely adopted in the market; however, these devices lack significant technological improvements. For instance, the functionality of the controllers (control chips) in these lighting devices has not seen substantial breakthroughs, resulting in relatively complex driver circuits. This complexity necessitates the use of more electronic components. Thus, it is difficult to improve the reliability of the driver power supply. Additionally, the complex driver circuits require larger spaces to accommodate the increased number of components, hindering efforts to miniaturize the driver power supply. These factors collectively lead to a significant increase in the cost of such lighting devices.

Moreover, these lighting devices may malfunction due to noise interference.

Furthermore, these lighting devices often require additional detection circuits to identify signals from the ballast and execute related control functions, further increasing the manufacturing costs thereof.

### SUMMARY

One embodiment of the present invention provides a highly compatible power controller includes a signal identification element, a switch driver, a switch element. The signal identification element includes a high-frequency signal identifier. The high-frequency signal recognizer includes a signal input terminal, a signal adjuster, a first timer, a second timer, an AND gate, and a latch. The signal input terminal receives a first input signal and transmits the first input signal to the signal adjuster. The signal adjuster generates an adjusted signal based on the first input signal and transmits the adjusted signal to the first timer. The first timer detects the frequency of the adjusted signal according to a preset detection window and generates a first detection signal, and transmits the first detection signal to the AND gate. The second timer generates a second detection signal according to the first input signal and a voltage startup threshold, and transmits the second detection signal to the AND gate to cause the AND gate to output a first logic signal to the latch. The latch controls the switch driver to turn on or off the switch element according to the first logic signal.

Further scope of applicability of the present application will become more apparent from the detailed description given hereinafter. However, it should be understood that the detailed description and specific examples, while indicating exemplary embodiments of the present invention, are given by way of illustration only, since various changes and modifications within the spirit and scope of the present invention will become apparent to those skilled in the art from this detailed description.

### BRIEF DESCRIPTION OF DRAWINGS

The present invention will become more fully understood from the detailed description given herein below and the accompanying drawings which are given by way of illustration only, and thus are not limitative of the present invention and wherein:

FIG. 1 is the block diagram of the circuit structure of the highly compatible power controller in accordance with the first embodiment of the present invention.

FIG. 2 is the block diagram of the circuit structure of the high-frequency signal identifier of the highly compatible power controller in accordance with the first embodiment of the present invention.

FIG. 3 is the block diagram of the circuit structure of the highly compatible power controller in accordance with the second embodiment of the present invention.

FIG. 4 is the block diagram of the circuit structure of the highly compatible power controller in accordance with the third embodiment of the present invention.

FIG. 5 is the block diagram of the circuit structure of the highly compatible power controller in accordance with the fourth embodiment of the present invention.

FIG. 6 is the block diagram of the circuit structure of the highly compatible power controller in accordance with the fifth embodiment of the present invention.

FIG. 7 is the block diagram of the circuit structure of the highly compatible power controller in accordance with the sixth embodiment of the present invention.

FIG. 8 is the circuit diagram of the lighting device driver having the power controller in accordance with the sixth embodiment of the present invention.

FIG. 9 is the schematic view of the utility power mode of the lighting device driver having the power controller in accordance with the sixth embodiment of the present invention.

FIG. 10 is the schematic view of the ballast mode of the lighting device driver having the power controller in accordance with the sixth embodiment of the present invention.

FIG. 11 is the block diagram of the circuit structure of the highly compatible power controller in accordance with the seventh embodiment of the present invention.

FIG. 12 is the block diagram of the circuit structure of the high-frequency signal identifier of the highly compatible power controller in accordance with the seventh embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. It should be understood that, when it is described that an element is “coupled” or “connected” to another element, the element may be “directly coupled” or “directly connected” to the other element or “coupled” or “connected” to the other element through a third element. In contrast, it should be understood that, when it is described that an element is “directly coupled” or “directly connected” to another element, there are no intervening elements.

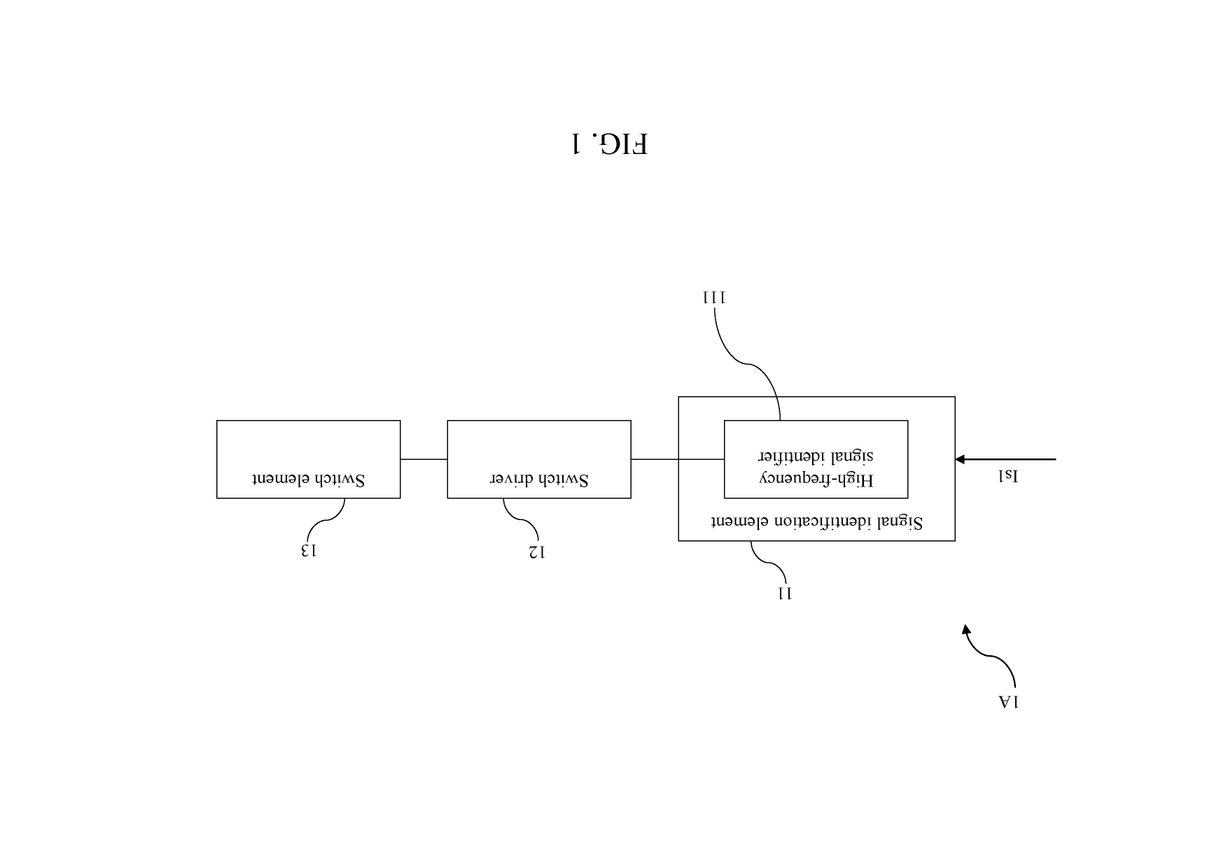

Please refer to FIG. 1, which is the block diagram of the circuit structure of the highly compatible power controller in accordance with the first embodiment of the present invention. As shown in FIG. 1, the power controller 1A includes a signal identification element 11, a switch driver 12, and a switch element 13.

The signal identification element 11 includes a high-frequency signal identifier 111. The high-frequency signal identifier 111 receives the first input signal Is1.

The switch driver 12 is connected to the high-frequency signal identifier 111. In this embodiment, the switch driver 12 may be a gate driver. In another embodiment, the switch driver 12 may be a signal amplifier or other components with signal amplification capabilities.

The switch element 13 is connected to the switch driver 12. In this embodiment, the switch element 13 may be a metal-oxide-semiconductor field-effect transistor (MOSFET). In another embodiment, the switch element 13 may also be a bipolar junction transistor (BJT) or other similar components.

The high-frequency signal identifier 111 executes a counting process within a preset time interval, which includes a preset number of counting cycles, to detect the number of sine waves in the first input signal Is1. The high-frequency signal identifier 111 generates a conduction signal when the number of sine waves in any counting cycle is greater than or equal to a preset threshold. The switch driver 12 activates the switch element 13 according to the conduction signal. The high-frequency signal identifier 111 then enters a deadlock state to stop the counting process.

Conversely, when the number of sine waves in each counting cycle is less than the preset threshold, the high-frequency signal identifier 111 enters a deadlock state, stopping the counting process.

Via the above counting mechanism and the specialized decision logic, the power controller 1 can effectively determine whether the first input signal Is1 is a signal from the ballast GH. When the number of sine waves in any counting cycle is greater than or equal to the preset threshold, the power controller 1 determines that the first input signal Is1 is a signal from the ballast GH, generates a conduction signal to activate the switch element 13, and outputs a direct-current signal. In this case, the power controller 1 operates in the ballast mode. The conduction signal mentioned above may be a direct-current signal, keeping the switch element 13 in the on state.

Conversely, when the number of sine waves in each counting cycle is less than the preset threshold, and the switch driver 12 activates the switch element 13 according to the conduction signal, the power controller 1 determines that the first input signal Is1 is noise. This noise may result from poor external switch contact or other factors. At this point, the high-frequency signal identifier 111 enters a deadlock state without generating a conduction signal to prevent the power controller 1 from malfunctioning.

The embodiment just exemplifies the present invention and is not intended to limit the scope of the present invention; any equivalent modification and variation according to the spirit of the present invention is to be also included within the scope of the following claims and their equivalents.

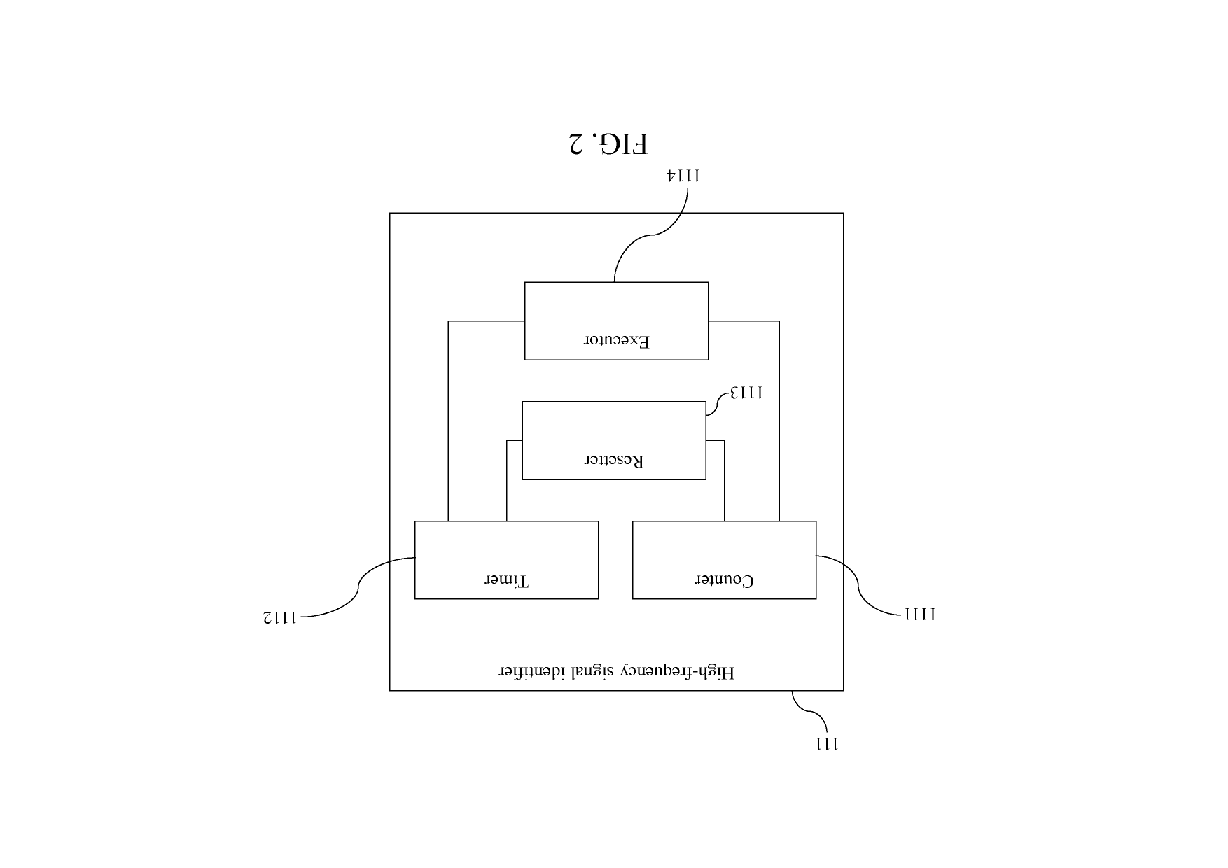

Please refer to FIG. 2, which is the block diagram of the circuit structure of the high-frequency signal identifier of the highly compatible power controller in accordance with the first embodiment of the present invention. As shown in FIG. 2, the high-frequency signal identifier 111 includes a counter 1111, a timer 1112, a resetter 1113, and an executor 1114.

The resetter 1113 is connected to the counter 1111 and the timer 1112. The counter 1111 and the timer 1112 are common integrated circuits and can be implemented using any existing circuit design, so no further details are provided here. The resetter 1113 may be a circuit with one or more of a resistor, a capacitor, or a diode.

The executor 1114 is connected to the counter 1111 and the timer 1112. The executor 1114 may be a circuit with one or more of a resistor, a capacitor, or a diode.

As mentioned earlier, the high-frequency signal identifier 111 can execute the counting process within a preset time interval. The counting process includes a preset number of counting cycles. When the high-frequency signal identifier 111 receives the first input signal Is1, the timer 1112 controls the executor 1114 to generate an execution signal to control the counter 1111 to execute the counting process and calculate the number of sine waves in the first input signal Is1. It also determines whether the number of sine waves in each counting cycle is greater than or equal to the preset threshold. The timer 1112 controls the duration of each counting cycle and, at the end of each cycle, controls the resetter 1113 to generate a reset signal to reset the counter 1111 for the next counting cycle.

For example, if the frequency threshold of the high-frequency signal identifier 111 is 20 kHz, and the frequency is not lower than 20 kHz, the high-frequency signal identifier 111 outputs a conduction signal to the switch driver 12, enabling the switch driver 12 to activate the switch element 13 based on the conduction signal. In this case, the sine wave period of the single high-frequency signal is 50 µs. The timer 1112 sets the counting cycle to 200 µs, and the preset time interval is 2000 µs. Thus, the counting process can include 10 counting cycles, and the preset threshold can be 4 (or 3).

When the number of sine waves in any counting cycle is greater than or equal to 4, the high-frequency signal identifier 111 determines that the first input signal Is1 meets the frequency threshold (20 kHz) and outputs a conduction signal to the switch driver 12, enabling the switch driver 12 to activate the switch element 13 to execute ballast mode.

Conversely, when the number of sine waves in each counting cycle is less than 4, the high-frequency signal identifier 111 determines that the first input signal Is1 does not meet the frequency threshold (20 kHz) and may be noise. At this point, the high-frequency signal identifier 111 enters a deadlock state without generating a conduction signal.

In another embodiment, the timer 1112 sets a counting cycle to 300 µs, and the preset time interval is 1500 µs. Thus, the counting process can include 5 counting cycles, and the preset threshold can be 6 (or 5). The sine wave period, counting cycle, preset time interval, and preset threshold mentioned above are examples and can be modified according to actual requirements.

Through the above circuit design, the high-frequency signal identifier 111 can achieve a highly efficient counting process, enabling the power controller 1 to effectively determine whether the first input signal Is1 is noise or a signal from the ballast GH, thereby preventing the power controller 1 from malfunctioning.

The embodiment just exemplifies the present invention and is not intended to limit the scope of the present invention; any equivalent modification and variation according to the spirit of the present invention is to be also included within the scope of the following claims and their equivalents.

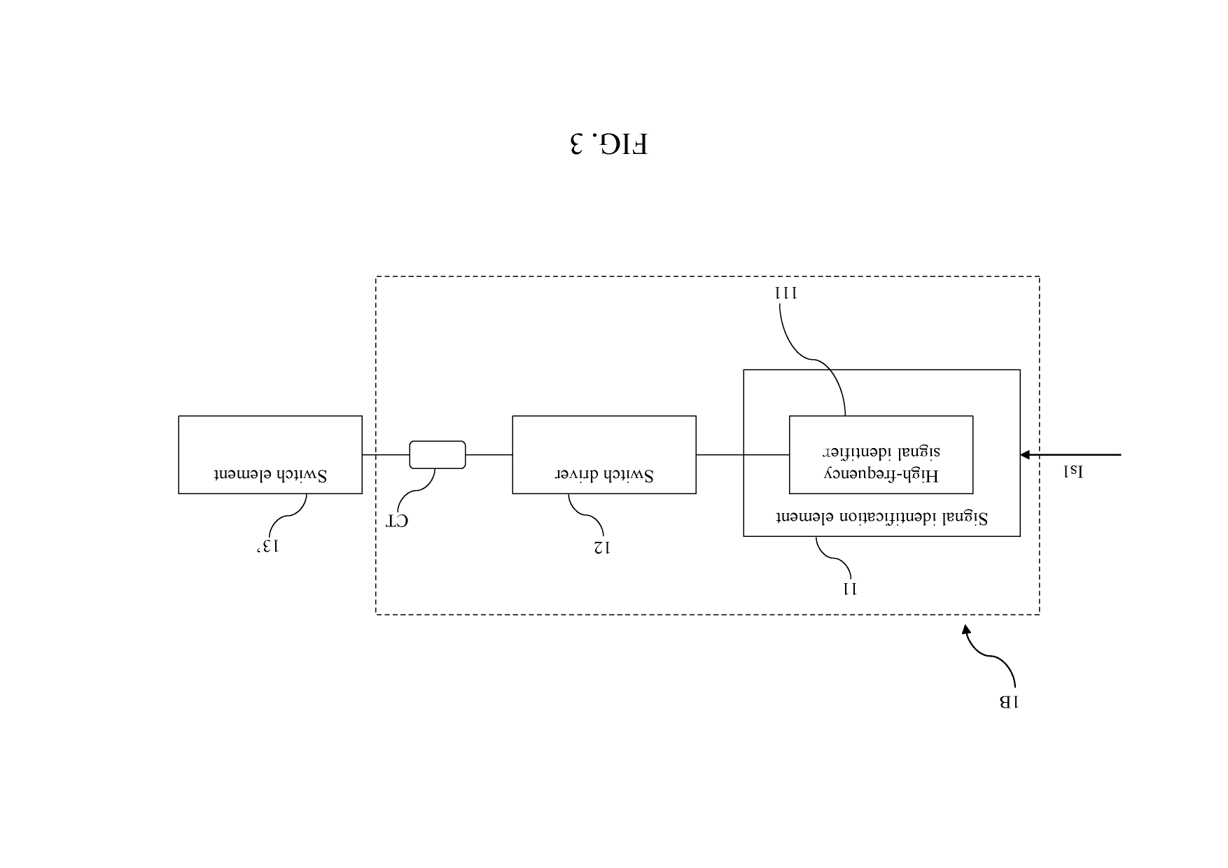

Please refer to FIG. 3, which is the block diagram of the circuit structure of the highly compatible power controller in accordance with the second embodiment of the present invention. As shown in FIG. 3, the power controller 1B includes a signal identification element 11 and a switch driver 12. The signal identification element 11 includes a high-frequency signal identifier 111. The switch driver 12 is connected to the high-frequency signal identifier 111. The functions of these components are the same as in the previous embodiment and will not be further elaborated here.

The difference between this embodiment and the first embodiment is that the power controller 1B further includes a port CT. The power controller 1B does not have a built-in switch element 13 but instead connects to an external switch element 13' via the port CT.

Similarly, the power controller 1B can execute the above-described counting process and decision logic to effectively determine whether the first input signal Is1 is a signal for the ballast GH or noise. When the power controller 1B determines that the first input signal Is1 is a signal from ballast GH, the power controller 1B operates in the ballast mode to drive the load. Conversely, when the power controller 1B determines that the first input signal Is1 is noise, the power controller 1B enters a deadlock state and does not generate a conduction signal.

The embodiment just exemplifies the present invention and is not intended to limit the scope of the present invention; any equivalent modification and variation according to the spirit of the present invention is to be also included within the scope of the following claims and their equivalents.

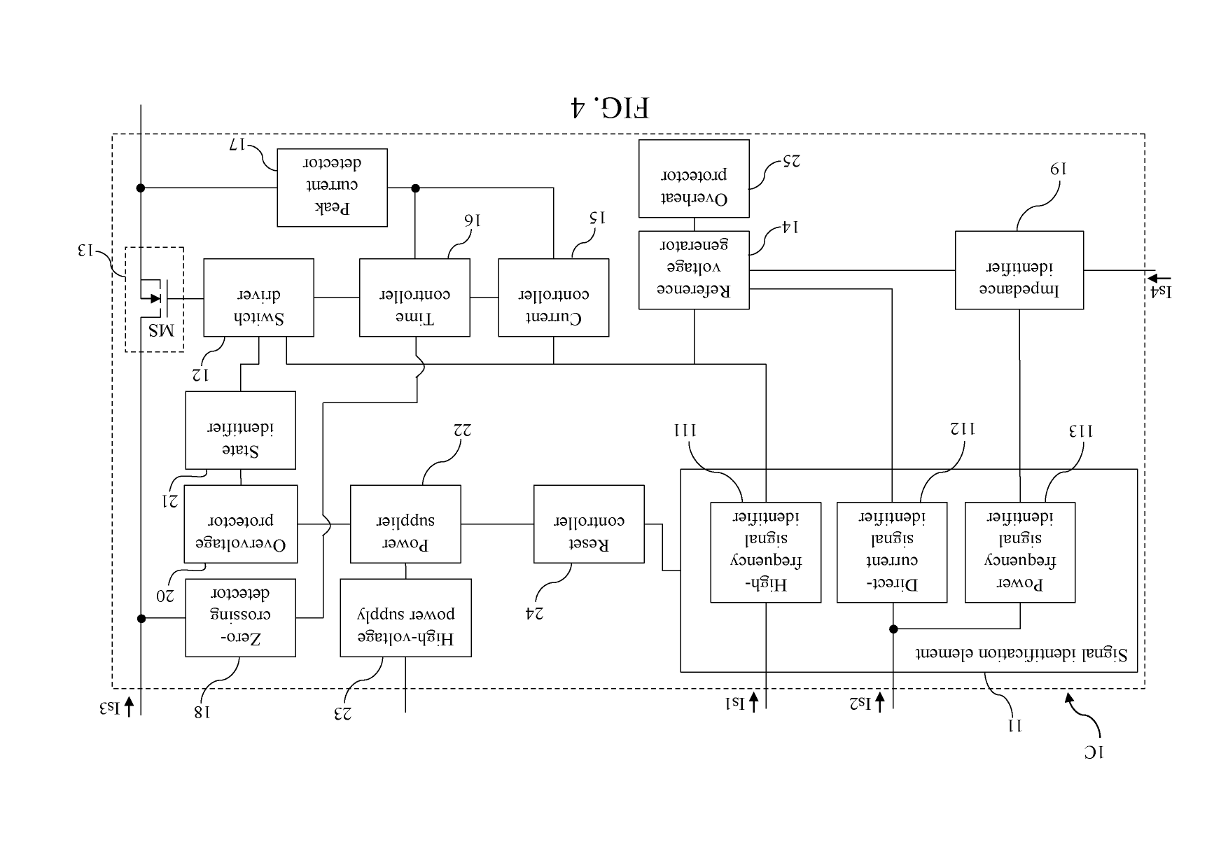

Please refer to FIG. 4, which is the block diagram of the circuit structure of the highly compatible power controller in accordance with the third embodiment of the present invention. As shown in FIG. 4, the power controller 1C includes a signal identification element 11, a switch driver 12, and a switch element 13. The signal identification element 11 includes a high-frequency signal identifier 111.

The difference between this embodiment and the first embodiment is that the signal identification element 11 further includes a direct-current signal identifier 112 and a power frequency signal identifier 113. Additionally, the power controller 1C includes a reference voltage generator 14, a current controller 15, a time controller 16, a peak current detector 17, a zero-crossing detector 18, an impedance identifier 19, an overvoltage protector 20, a state identifier 21, a power supplier 22, a high-voltage power supply 23, a reset controller 24, and an overheat protector 25. Since the direct-current signal identifier 112, power frequency signal identifier 113, and other listed components have already been applied in currently available power controllers, the circuit structures thereof will not be further elaborated. Furthermore, in this embodiment, the switch element 13 is a transistor MS, which is a metal-oxide-semiconductor field-effect transistor.

The high-voltage power supply 23 is connected to the power supplier 22. The power supplier 22 is connected to the reset controller 24 and the overvoltage protector 20. The overvoltage protector 20 is connected to the state identifier 21. The state identifier 21 is connected to the switch driver 12.

The high-voltage power supply 23 divides the rectified DC voltage to generate a drive voltage. The power supplier 22 steps down and regulates the drive voltage. When the high-voltage power supply 23 is powered on, the reset controller 24 resets all components of the power controller 1C. The overvoltage protector 20 detects whether there is an overvoltage or undervoltage condition to generate a status detection signal. The state identifier 21 restarts or deadlocks the switch driver 12 according to the status detection signal.

The direct-current signal identifier 112 is connected to the reference voltage generator 14. The reference voltage generator 14 is connected to the current controller 15. The current controller 15 is connected to the time controller 16 and the peak current detector 17. The time controller 16 is connected to the zero-crossing detector 18, the peak current detector 17, and the switch driver 12.

The direct-current signal identifier 112 receives the second input signal Is2 and outputs a direct-current identification signal to the reference voltage generator 14 when determining that the second input signal Is2 is a direct-current signal, thereby generating a reference voltage. The peak current detector 17 detects the peak current when the switch element 13 is turned on and generates a peak current detection signal. The current controller 15 generates a current control signal according to the reference voltage and the peak current detection signal. The time controller 16 generates the first pulse-width modulation signal according to the current control signal, peak current detection signal, and the third input signal Is3 from the zero-crossing detector 18 to control the switch driver 12 in operating the switch element 13. This mode is the direct-current power mode (which is compatible with adapters, batteries, and other DC power sources).

The power frequency signal identifier 113 is connected to the impedance identifier 19. The impedance identifier 19 is connected to the reference voltage generator 14. The power frequency signal identifier 113 receives the second input signal Is2 and outputs a power frequency identification signal to the impedance identifier 19 when determining that the second input signal Is2 is a power frequency signal. The impedance identifier 19 outputs an impedance identification signal to the reference voltage generator 14 according to the fourth input signal Is4 to generate a reference voltage. The current controller 15 generates a current control signal according to the reference voltage and the peak current detection signal. The time controller 16 generates the second pulse-width modulation signal based on the current control signal, peak current detection signal, and zero-crossing detection signal to control the switch driver 12 in operating the switch element 13. This mode is the utility power mode (compatible with utility power).

The overheat protector 25 detects the temperature of the power controller 1C and transmits an overheat protection signal to the reference voltage generator 14 to reduce the reference voltage when the temperature exceeds a threshold value, thereby performing temperature regulation.

The power controller 1C can perform the utility power mode or the direct-current power mode through the aforementioned components. Therefore, the power controller 1C is compatible with ballast GH, utility power, and direct-current power sources (such as adapters and batteries) without requiring additional detection circuits, achieving high compatibility. Furthermore, the complexity of the drive circuit is thereby reduced, allowing the power controller 1C to be miniaturized and lowering manufacturing costs.

The embodiment just exemplifies the present invention and is not intended to limit the scope of the present invention; any equivalent modification and variation according to the spirit of the present invention is to be also included within the scope of the following claims and their equivalents.

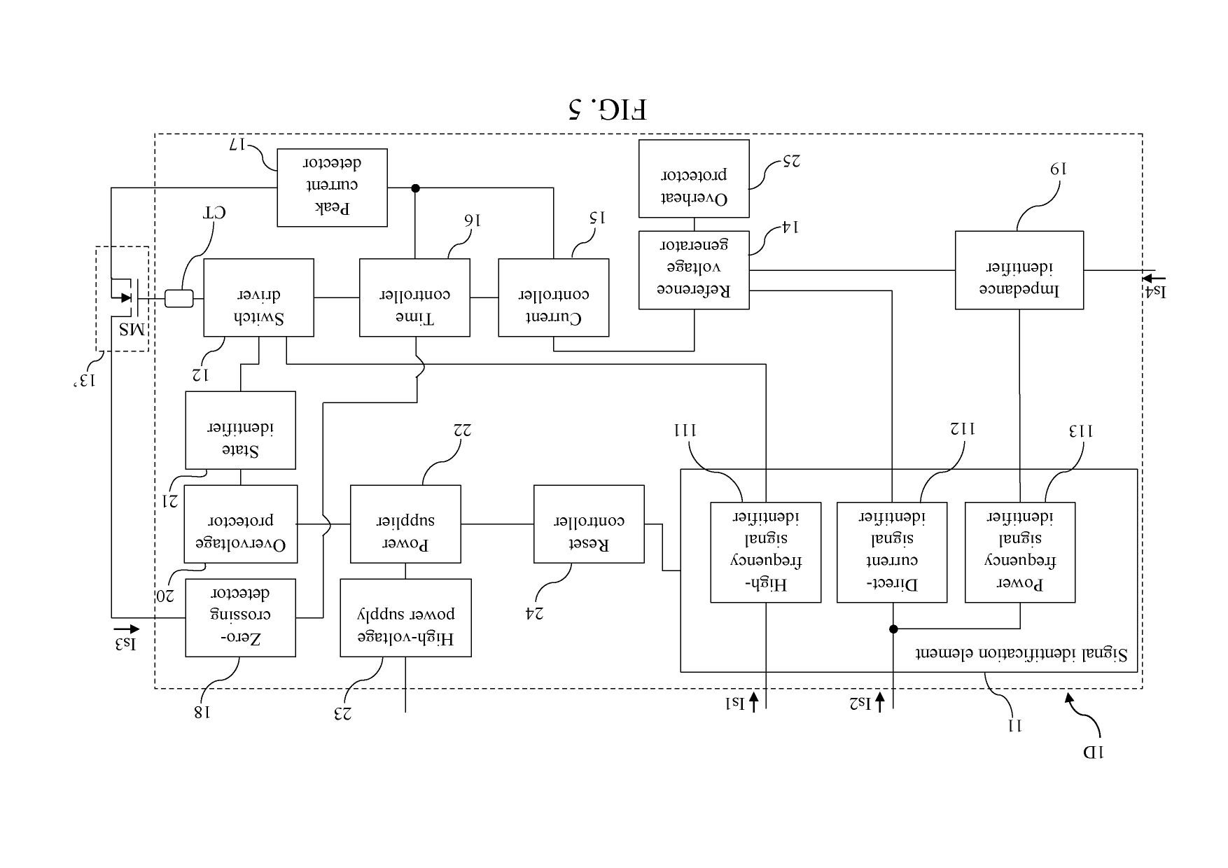

Please refer to FIG. 5, which is the block diagram of the circuit structure of the highly compatible power controller in accordance with the fourth embodiment of the present invention. As shown in FIG. 5, the power controller 1D includes a signal identification element 11, a switch driver 12, a reference voltage generator 14, a current controller 15, a time controller 16, a peak current detector 17, a zero-crossing detector 18, an impedance identifier 19, an overvoltage protector 20, a state identifier 21, a power supplier 22, a high-voltage power supply 23, a reset controller 24, and an overheat protector 25. The signal identification element 11 includes a high-frequency signal identifier 111, a direct-current signal identifier 112, and a power frequency signal identifier 113.

The functions of these components are the same as in the previous embodiments and will not be further elaborated. Unlike the third embodiment, the power controller 1D further includes a port CT. The power controller 1 does not have a built-in switch element 13 but instead connects to an external switch element 13' through the port CT. In this embodiment, the switch element 13' is a transistor MS, which is a metal-oxide-semiconductor field-effect transistor.

The embodiment just exemplifies the present invention and is not intended to limit the scope of the present invention; any equivalent modification and variation according to the spirit of the present invention is to be also included within the scope of the following claims and their equivalents.

It is worthy to point out that the functionality of currently available controllers (control chips) in lighting devices has not seen substantial breakthroughs, resulting in relatively complex driver circuits. This complexity necessitates the use of more electronic components. Thus, it is difficult to improve the reliability of the driver power supply. Additionally, the complex driver circuits require larger spaces to accommodate the increased number of components, hindering efforts to miniaturize the driver power supply. These factors collectively lead to a significant increase in the cost of such lighting devices. Furthermore, these lighting devices often require additional detection circuits to identify signals from the ballast and execute related control functions, further increasing the manufacturing costs thereof. By contrast, according to one embodiment of the present invention, the power controller includes a signal identification element, a switch driver, a switch element. The signal identification element includes a high-frequency signal identifier for receiving a first input signal. The switch driver is connected to the high-frequency signal identifier. The switch element is connected to the switch driver. The high-frequency signal identifier executes a counting process within a preset time interval. The counting process includes a preset number of counting cycles for detecting the number of sine waves in the first input signal. The high-frequency signal identifier generates a conduction signal when the number of sine waves in any one of the counting cycles is greater than or equal to a preset threshold, and the switch driver activates the switch element according to the conduction signal. Through the above counting mechanism and the specialized decision-making logic thereof, the power controller can effectively determine whether the first input signal is a ballast signal and, if so, execute the ballast mode to drive the load. In this way, the power controller can be compatible with ballasts so as to meet actual requirements.

According to one embodiment of the present invention, the high-frequency signal identifier of the power controller enters a deadlock state, halting the counting process, when the number of sine waves in each counting cycle is less than the preset threshold. Via the above counting mechanism and the specialized decision-making logic thereof, the power controller can effectively determine whether the first input signal is noise. If the first input signal is determined to be noise (e.g., caused by poor external switch contact or other factors), the system enters a deadlock state and does not generate a conduction signal. Thus, the high-frequency signal identifier can effectively prevent the power controller from malfunctioning, ensuring high reliability.

Also, according to one embodiment of the present invention, the high-frequency signal identifier of the power controller comprises a counter, a timer, a resetter, and an executor. The resetter is connected to the counter and the timer, while the executor is connected to the counter and the timer. The timer controls the executor to generate an execution signal to direct the counter to execute the counting process and calculate the number of sine waves in the first input signal. The timer also controls the duration of each counting cycle and, at the end of each cycle, controls the resetter to generate a reset signal to reset the counter for the next cycle. Therefore, the high-frequency signal identifier can achieve a highly efficient counting process through a simple circuit design, enabling the power controller to effectively distinguish whether the first input signal is noise or a ballast signal.

Further, according to one embodiment of the present invention, the power controller further includes a reference voltage generator, a current controller, a time controller, a peak current detector, a zero-crossing detector, and an impedance identifier. The signal identification component also includes a direct-current signal identifier and a power frequency signal identifier. Thus, the power controller can execute either a utility power mode or a direct-current power mode through the above components. Consequently, the power controller is compatible with ballasts, utility power, and direct-current power sources (e.g., adapters, batteries) without requiring additional detection circuits, thereby achieving high compatibility. Moreover, the complexity of the driver circuit is reduced, enabling the power controller to achieve miniaturization and lower manufacturing costs.

Moreover, according to one embodiment of the present invention, the switch element of the power controller may also be an external switch element. The power controller can include a port through which the switch driver connects to the external switch element. Thus, the power controller can be configured with either an integrated switch element or an external switch element, depending on practical requirements, such that the power controller can conform to the requirements of different applications.

Furthermore, according to one embodiment of the present invention, the power controller can achieve the desired functionality through a simple circuit design and operational mechanism. As a result, it not only reduces manufacturing costs but also achieves the intended performance. This significantly enhances the practicality of the power controller, making it more versatile in application and more flexible in use. As described above, the highly compatible power controller according to the embodiments of the present invention can achieve great technical effects.

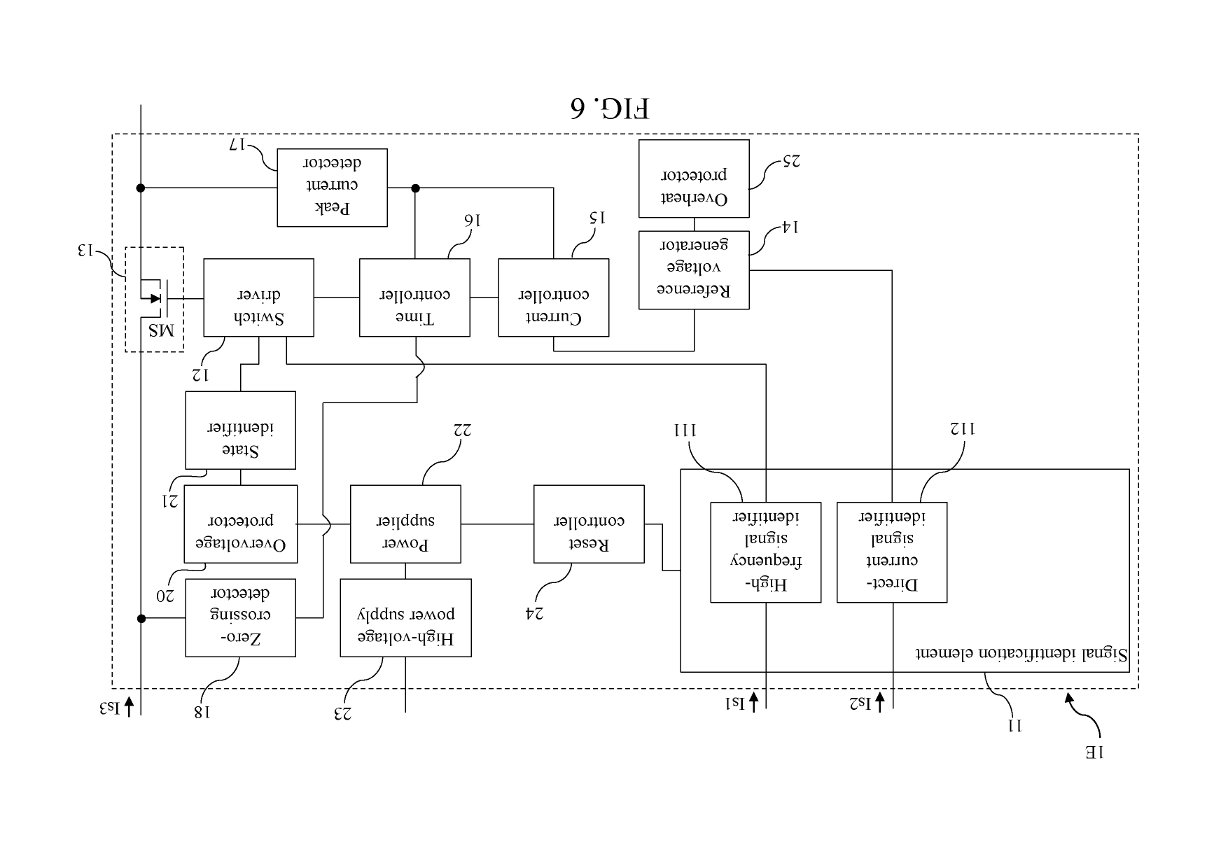

Please refer to FIG. 6, which is the block diagram of the circuit structure of the highly compatible power controller in accordance with the fifth embodiment of the present invention. As shown in FIG. 6, the difference between this embodiment and the third embodiment is that the signal identification element 11 of the power controller 1E includes a high-frequency signal identifier 111 and a direct-current signal identifier 112 but does not include a power frequency signal identifier 113. Additionally, the power controller 1E does not include an impedance identifier 19.

The embodiment just exemplifies the present invention and is not intended to limit the scope of the present invention; any equivalent modification and variation according to the spirit of the present invention is to be also included within the scope of the following claims and their equivalents.

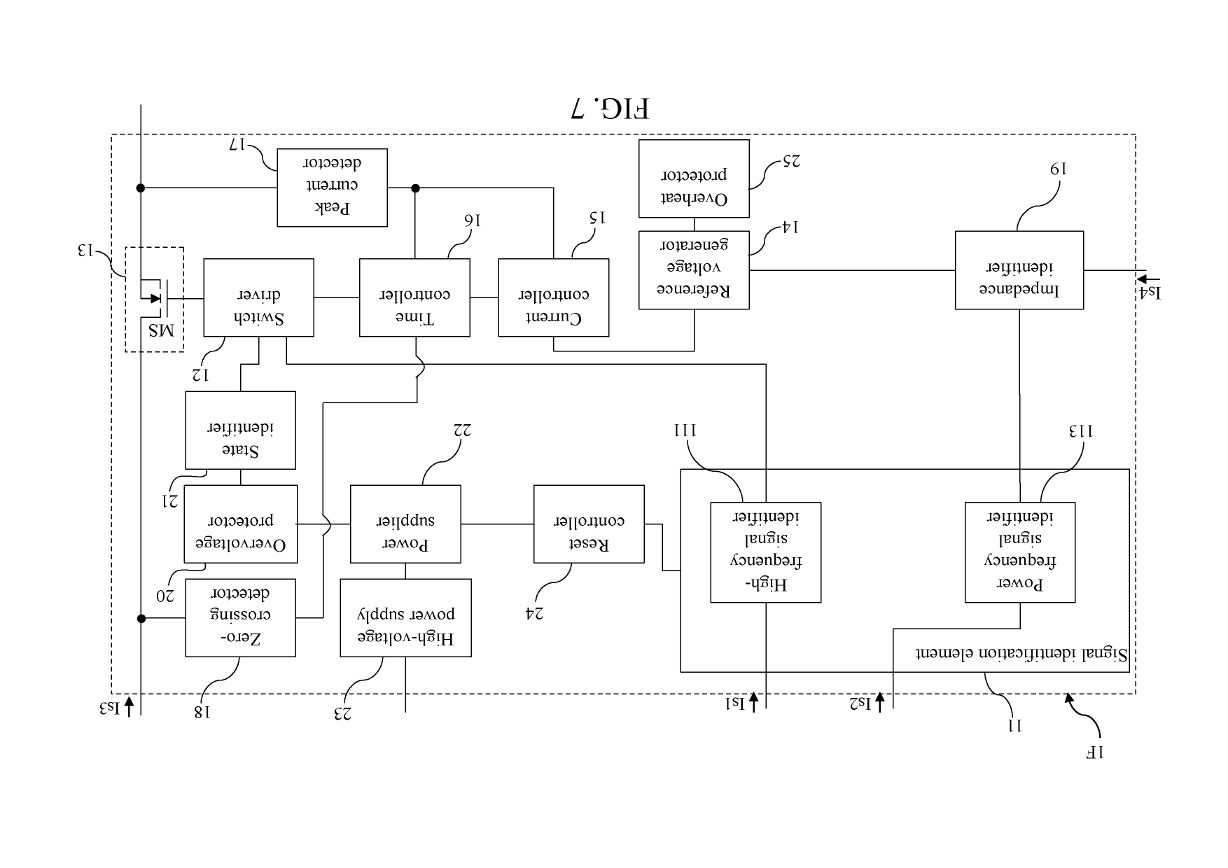

Please refer to FIG. 7, which is the block diagram of the circuit structure of the highly compatible power controller in accordance with the sixth embodiment of the present invention. As shown in FIG. 7, the difference between this embodiment and the third embodiment is that the signal identification element 11 of the power controller 1F includes a high-frequency signal identifier 111 and a power frequency signal identifier 113 but does not include a direct-current signal identifier 112.

The embodiment just exemplifies the present invention and is not intended to limit the scope of the present invention; any equivalent modification and variation according to the spirit of the present invention is to be also included within the scope of the following claims and their equivalents.

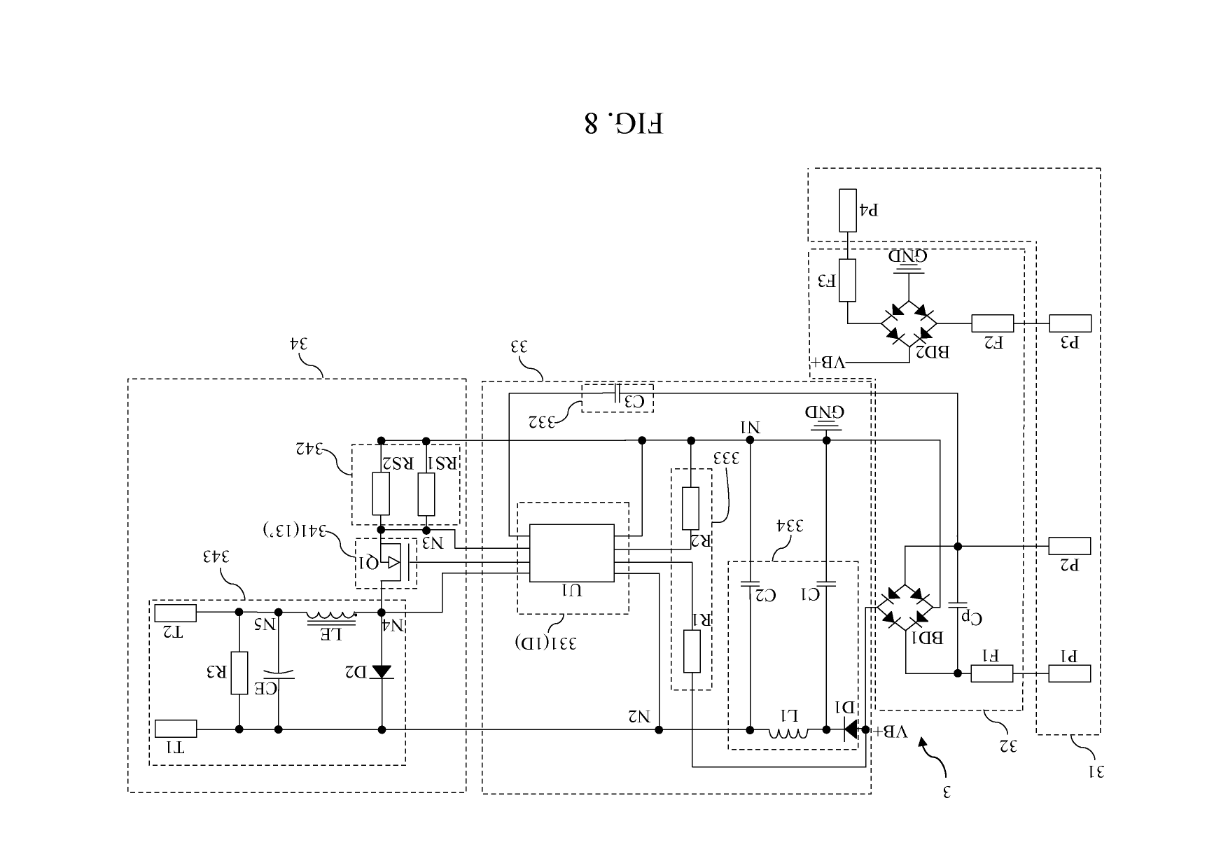

Please refer to FIG. 8, which is the circuit diagram of the lighting device driver having the power controller in accordance with the sixth embodiment of the present invention. FIG. 8 provides an example of the circuit structure of the lighting device driver 3. This embodiment is for illustrative purposes only; the circuit structures of the input module 31, rectification module 32, driving control module 33, and power conversion module 34 can be modified as needed, and the invention is not limited thereto. As shown in FIG. 8, the lighting device driver 3 includes an input module 31, a rectification module 32, a driving control module 33, and a power conversion module 34.

The input module 31 includes a first input terminal P1, a second input terminal P2, a third input terminal P3, and a fourth input terminal P4.

The rectification module 32 is connected to the input module 31 and includes a first rectifier BD1, a second rectifier BD2, a first fuse F1, a second fuse F2, a third fuse F3, and a capacitor Cp. The first end of the first rectifier BD1 is connected to the second input terminal P2; the second end of the first rectifier BD1 is connected to the rectified signal output terminal VB+; the third end of the first rectifier BD1 is connected to the first input terminal P1 via the first fuse F1; and the fourth end of the first rectifier BD1 is connected to the first node N1. The first node N1 is connected to the ground GND. The first end of the second rectifier BD2 is connected to the fourth input terminal P4 via the third fuse F3; the second end of the second rectifier BD2 is connected to the rectified signal output terminal VB+; the third end of the second rectifier BD2 is connected to the third input terminal P3 via the second fuse F2; and the fourth end of the second rectifier BD2 is connected to the ground GND. In one embodiment, the first rectifier BD1 and the second rectifier BD2 can be bridge rectifiers (full-wave or half-wave rectifiers). In another embodiment, they can also be bipolar junction transistors, circuits incorporating bipolar junction transistors, or any other currently available circuits or electronic components with rectification functions.

The driving control module 33 is connected to the rectification module 32 and includes a control unit 331, a signal identification unit 332, an impedance identification and detection unit 333, and a direct-current signal smoothing unit 334, which are connected to each other. The control unit 331 may have at least one signal identification interface and is connected to the signal identification unit 332 via this interface. The control unit 331 includes a controller U1, which may serve as the power controller 1D of the fourth embodiment (the power controller 1D of the fourth embodiment is connected to an external switch element 13’). The direct-current signal smoothing unit 334 includes a first diode D1, an inductor L1, a first capacitor C1, and a second capacitor C2. The anode of the first diode D1 is connected to the rectified signal output terminal VB+, and the cathode thereof is connected to one end of the inductor L1, which is further connected to the first node N1 via the first capacitor C1. The other end of the inductor L1 is connected to the second node N2, which is further connected to the first node N1 via the second capacitor C2. The impedance identification and detection unit 333 includes a plurality of resistors connected in series. In this embodiment, the impedance identification and detection unit 333 includes a first resistor R1 and a second resistor R2. The two ends of the first resistor R1 are connected to the rectified signal output terminal VB+ and the control unit 331, respectively. The two ends of the second resistor R2 are connected to the control unit 331 and the first node N1, respectively. The signal identification unit 332 includes a third capacitor C3, which is connected to the first input terminal P1 via the capacitor Cp, enabling a portion of the input signal Is’, to couple to the third capacitor C3 (the signal identification unit 332). In another embodiment, the control unit 331 may also serve as the power controller 1A, 1B, 1C, 1E, or 1F of the first, second, third, fifth, or sixth embodiments.

The power conversion module 34 is connected to the control unit 331. The power conversion module 34 includes a switching unit 341, a sampling unit 342, and an output unit 343. The switching unit 341 includes a switch Q1 (which serves as the external switch element 13’ of the fourth embodiment), and may be a metal-oxide-semiconductor field-effect transistor. Alternatively, the switch Q1 can also be a bipolar junction transistor or other similar components. The first end of the switch Q1 is connected to the control unit 331, the second end of the switch Q1 is connected to the third node N3, and the third end of the switch Q1 is connected to the fourth node N4. Both the third node N3 and the fourth node N4 are connected to the control unit 331. The output unit 343 includes a second diode D2, an energy storage inductor LE, an electrolytic capacitor CE, a third resistor R3, a first output terminal T1, and a second output terminal T2. The anode and cathode of the second diode D2 are connected to the fourth node N4 and the second node N2, respectively. The two ends of the energy storage inductor LE are connected to the fourth node N4 and the fifth node N5, respectively. The two ends of the electrolytic capacitor CE are connected to the fifth node N5 and the second node N2, respectively. The two ends of the third resistor R3 are connected to the fifth node N5 and the second node N2, respectively. The second node N2 and the fifth node N5 are connected to the first output terminal T1 and the second output terminal T2, respectively.

The embodiment just exemplifies the present invention and is not intended to limit the scope of the present invention; any equivalent modification and variation according to the spirit of the present invention is to be also included within the scope of the following claims and their equivalents.

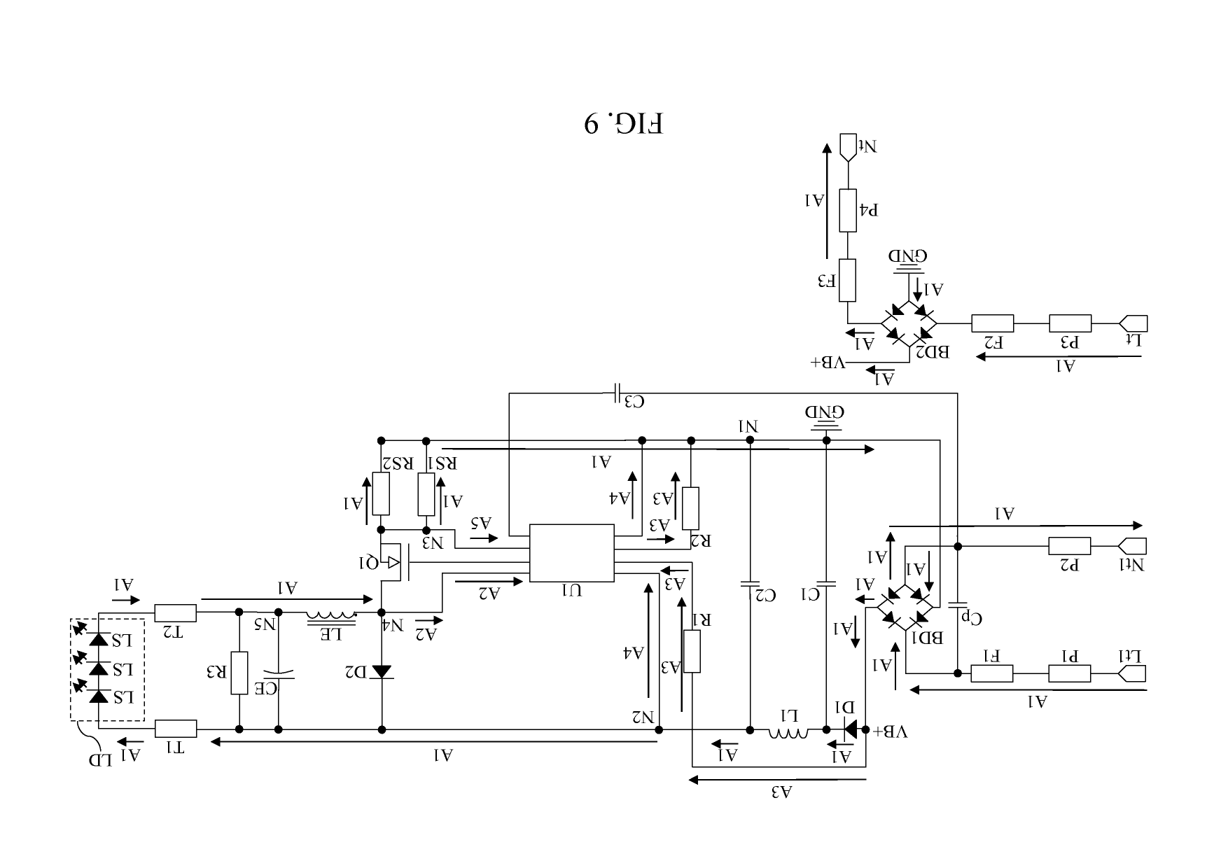

Please refer to FIG. 9, which is the schematic view of the utility power mode of the lighting device driver having the power controller in accordance with the sixth embodiment of the present invention. As shown in FIG. 9, the load LD includes a plurality of light sources LS, which may be light-emitting diodes. The load LD is connected to the first output terminal T1 and the second output terminal T2 of the output unit 343. When the input module 31 is connected to the utility power (Lt1, Nt1, Lt, and Nt represent the output terminals of the utility power), the input module 31 couples the external input signal Is, and the rectification module 32 rectifies the input signal Is to generate a rectified signal. The impedance identification and detection unit 333 of the driving control module 33 detects the impedance of the rectified signal, as indicated by the arrow A3 (this signal corresponds to the second input signal Is2 in the fourth embodiment). The control unit 331 executes the utility power mode when the control unit 331 determines that the second input signal Is2 is a power frequency signal. The direct-current signal smoothing unit 334 converts the rectified signal into a smooth direct-current signal (used to drive the high-voltage power supply 23 in the fourth embodiment) to supply power to the driving control module 33, as indicated by the arrow A4. The sampling unit 342 of the power conversion module 34 generates a feedback signal according to the peak current during the conduction of the switch element 341. The control unit 331 adjusts the pulse-width modulation signal according to the feedback signal (this feedback signal is inputted to the peak current detector 17 in the fourth embodiment) to control the power conversion module 34 for power conversion, as indicated by the arrow A5. In this case, the switch element 341 is continuously turned on and off, allowing the power conversion module 34 to perform power conversion. The control unit 331 can also receive a zero-crossing detection signal from the fourth node N4, as indicated by arrow A2 (this signal corresponds to the third input signal Is3 in the fourth embodiment), to perform zero-crossing detection. The rectified signal drives the load LD via the power conversion module 34 (including the switch element 341, output unit 343, and sampling unit 342). The path of the rectified signal is shown by the arrow A1. The lighting device driver 3 can also operate in a direct-current power mode.

The embodiment just exemplifies the present invention and is not intended to limit the scope of the present invention; any equivalent modification and variation according to the spirit of the present invention is to be also included within the scope of the following claims and their equivalents.

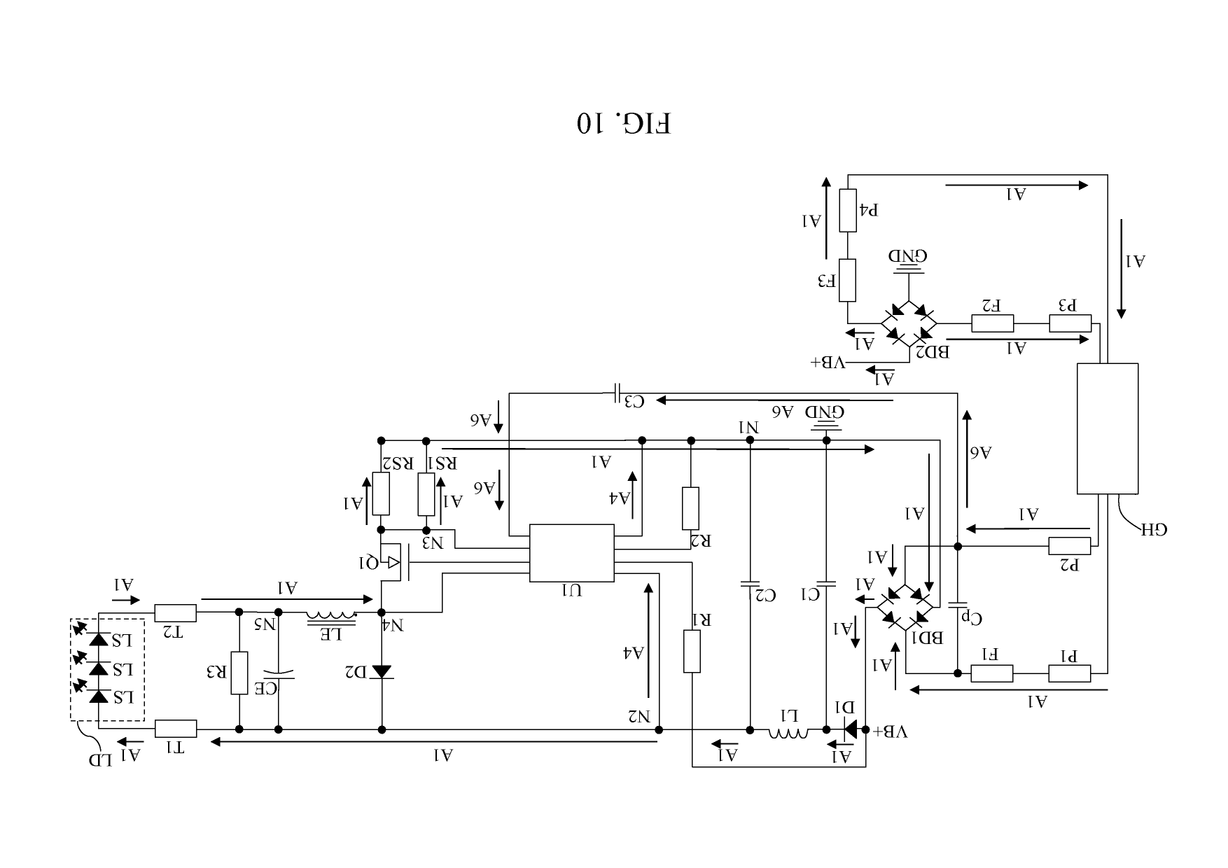

Please refer to FIG. 10, which is the schematic view of the ballast mode of the lighting device driver having the power controller in accordance with the sixth embodiment of the present invention. As shown in FIG. 10, the load LD includes a plurality of light sources LS, which may be light-emitting diodes. The load LD is connected to the first output terminal T1 and the second output terminal T2 of the output unit 343. When the input module 31 is connected to the ballast GH, the input module 31 generates an input signal Is, and the rectification module 32 rectifies the input signal Is to generate a rectified signal. A portion of the input signal Is’ is coupled to the signal identification unit 332 via the capacitor Cp of the rectification module 32 (this signal corresponds to the first input signal Is1 in the fourth embodiment), as indicated by the arrow A6. The control unit 331 enters the ballast mode when the counting process identifies the signal as originating from the ballast GH. In the ballast mode, the control unit 331 generates a direct-current signal to control the continuous conduction of the switch element in the power conversion module 34. In this case, the switch element 341 remains in a continuously conducting state, forming a closed-loop circuit. Consequently, the rectified signal generated from the input signal of the ballast GH can directly drive the load LD. The direct-current signal smoothing unit 334 converts the rectified signal into a smooth direct-current signal to supply power to the driving control module 33, as indicated by the arrow A4. The rectified signal drives the load LD after being further smoothed via the power conversion module 34 (including the switch element 341, output unit 343, and sampling unit 342). The path of the rectified signal Rs is shown by the arrow A1.

The embodiment just exemplifies the present invention and is not intended to limit the scope of the present invention; any equivalent modification and variation according to the spirit of the present invention is to be also included within the scope of the following claims and their equivalents.

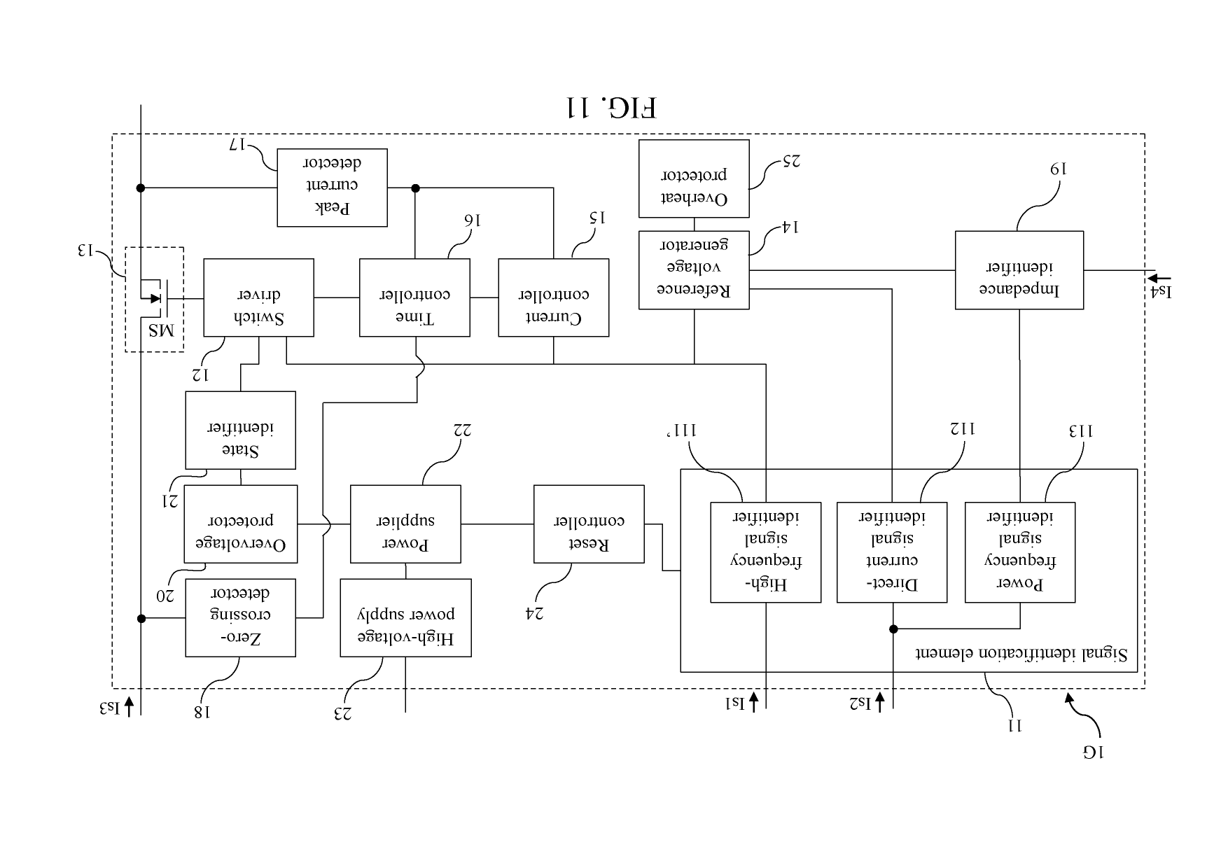

Please refer to FIG. 11, which is the block diagram of the circuit structure of the highly compatible power controller in accordance with the seventh embodiment of the present invention. As shown in FIG. 11, the power controller 1G includes a signal recognition element 11, a switch driver 12, and a switch element 13. The signal recognition element 11 includes a high-frequency signal recognizer 111’, a direct-current signal recognizer 112, and a power frequency signal recognizer 113. In another embodiment, the switch element 13 may also be an external switch element (as shown in FIG. 5).

Additionally, the power controller 1G further includes a reference voltage generator 14, a current controller 15, a time controller 16, a peak current detector 17, a zero-crossing detector 18, an impedance recognizer 19, an overvoltage protector 20, a status recognizer 21, a power supplier 22, a high-voltage power supply 23, a reset controller 24, and an overheat protector 25.

The above components are substantially the same as those in the third embodiment, and thus will not be redundantly described herein. The difference from the third embodiment lies in the distinct circuit structure of the high-frequency signal recognizer 111’.

The embodiment just exemplifies the present invention and is not intended to limit the scope of the present invention; any equivalent modification and variation according to the spirit of the present invention is to be also included within the scope of the following claims and their equivalents.

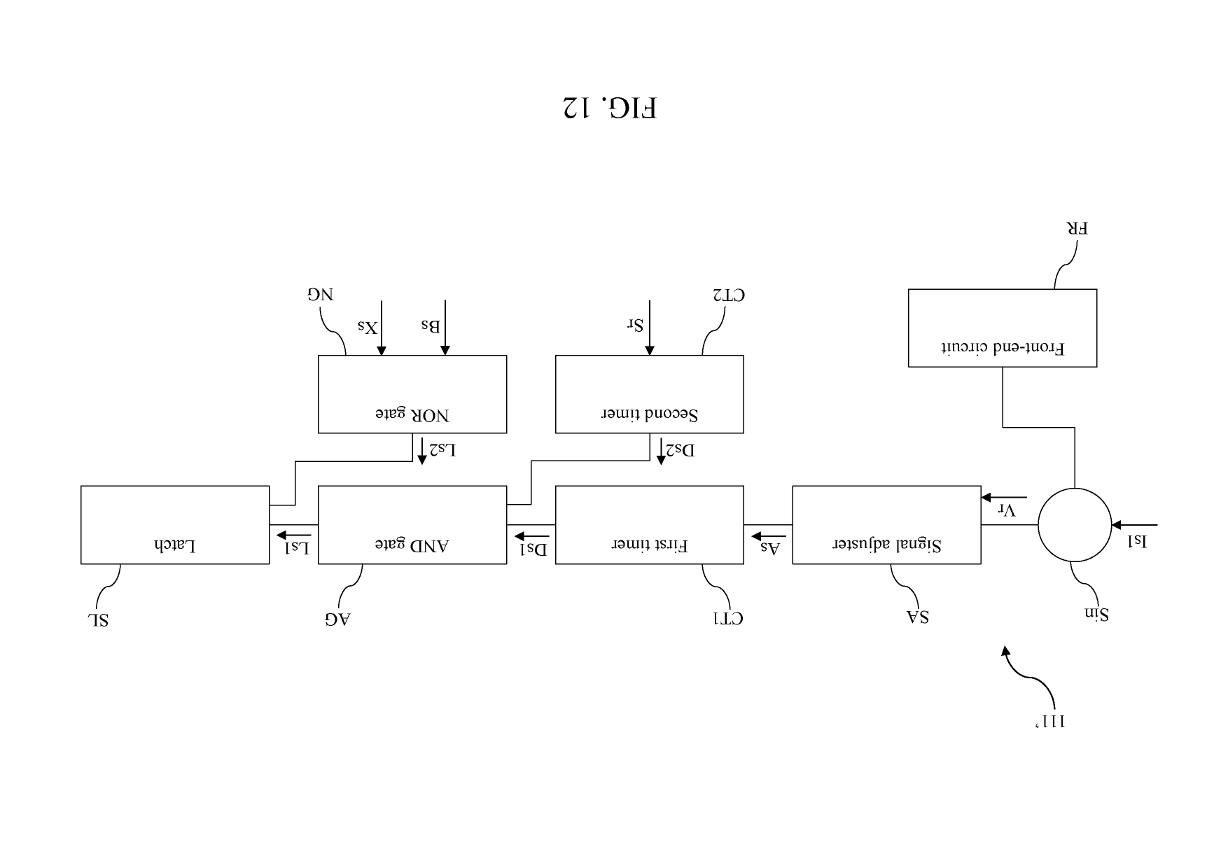

Please refer to FIG. 12, which is the block diagram of the circuit structure of the high-frequency signal identifier of the highly compatible power controller in accordance with the seventh embodiment of the present invention. As shown in FIG. 12, the high-frequency signal recognizer 111’ includes a signal input terminal Sin, a signal adjuster SA, a first timer CT1, a second timer CT2, an AND gate AG, a NOR gate NG, and a latch SL.

The signal input terminal Sin is connected to the signal adjuster SA.

The signal adjuster SA is connected to the first timer CT1 and a reference voltage source. In this embodiment, the signal adjuster SA may be an inverter. In another embodiment, the signal adjuster SA may be a comparator, an operational amplifier, or other similar components.

The first timer CT1 and the second timer CT2 are connected to the AND gate AG. The second timer CT2 is also connected to another reference voltage source.

The AND gate AG and the NOR gate NG are connected to the latch SL.

The signal input terminal Sin receives the first input signal Is1 and transmits the first input signal Is1 to the signal adjuster SA. The signal input terminal Sin may also be connected to a front-end circuit FR, which includes multiple resistors. This front-end circuit FR may preliminarily process the first input signal Is1 to perform peak limiting and signal level stabilization, providing voltage division and regulation functions.

The signal adjuster SA then generates an adjusted signal As based on the first input signal Is1 and transmits the adjusted signal As to the first timer CT1. Here, the signal adjuster SA may receive a reference signal Vr from the reference voltage source as a comparison benchmark for the first input signal Is1. The signal adjuster SA generates the adjusted signal As based on the reference signal Vr and the first input signal Is1 and transmits the adjusted signal As to the first timer CT1. The adjusted signal As generated by the signal adjuster SA may be a square wave, which is a signal easily recognizable by the first timer CT1.

The first timer CT1 detects the frequency of the adjusted signal As according to a preset detection window and generates a first detection signal Ds1, which is transmitted to the AND gate AG. The first timer CT1 may detect the frequency of the adjusted signal As within the preset detection window at a preset detection cycle. The first timer CT1 may detect the frequency of the adjusted signal As at each preset detection cycle until the preset detection window ends. For example, the preset detection window may be 2 ms, but is not limited thereto. In another embodiment, the preset detection window may also be 3 ms or 4 ms, adjustable according to actual needs. For example, the preset detection cycle may be 500 μs, but is not limited thereto. In another embodiment, the preset detection cycle may also be 400 μs or 600 μs, adjustable according to actual needs.

The second timer CT2 generates a second detection signal Ds2 based on the first input signal Is1 and the voltage startup threshold Sr, and transmits the second detection signal Ds2 to the AND gate AG. The second timer CT2 may receive the voltage startup threshold Sr from another reference voltage source as a comparison benchmark for the first input signal Is1. The second timer CT2 compares the first input signal Is1 with the voltage startup threshold Sr to generate the second detection signal Ds2 and transmits the second detection signal Ds2 to the AND gate AG.

The AND gate AG outputs a first logic signal Ls1 based on the first detection signal Ds1 and the second detection signal Ds2, and transmits the first logic signal Ls1 to the latch SL.

The NOR gate NG generates a second logic signal Ls2 based on an output signal of the high-voltage power supply 23, and transmits the second logic signal Ls2 to the latch SL.

The latch SL controls the switch driver 12 to turn on or off the switch element 13 according to the first logic signal Ls1 and the second logic signal Ls2.

The first timer CT1 generates the first detection signal Ds1 at high level when determining that the frequency of the adjusted signal As is greater than or equal to the frequency threshold, and transmits the first detection signal Ds1 at high level to the AND gate AG. Conversely, the first timer CT1 generates the first detection signal Ds1 at low level when determining that the frequency of the adjusted signal As is below the frequency threshold, and transmits the first detection signal Ds1 at low level to the AND gate AG.

The second timer CT2 generates the second detection signal Ds2 at high level when the first input signal Is1 is greater than or equal to the voltage startup threshold Sr, and transmits the second detection signal Ds2 at high level to the AND gate AG. Conversely, the second timer CT2 generates the second detection signal Ds2 at low level when the first input signal Is1 is below the voltage startup threshold Sr and transmits the second detection signal Ds2 at low level to the AND gate AG. In another embodiment, the second timer CT2 generates the second detection signal Ds2 at high level only when the duration of the first input signal Is1 being greater than or equal to the voltage startup threshold Sr exceeds a preset time interval (e.g., 2 μs, 3 μs, or 5 μs, adjustable according to actual needs). In yet another embodiment, the second timer CT2 detects the frequency of the first input signal Is1 within the preset detection window at the preset detection cycle when the duration of the first input signal Is1 being greater than or equal to the voltage startup threshold Sr exceeds the preset time interval. The second timer CT2 may detect the frequency of the first input signal Is1 at each preset detection cycle until the preset detection window ends. Then, the second timer CT2 generates the second detection signal Ds2 at high level when determining that the frequency of the first input signal Is1 is greater than or equal to the frequency threshold. For example, the preset detection window may be 2 ms, but is not limited thereto. In another embodiment, the preset detection window may also be 3 ms or 4 ms, adjustable according to actual needs. For example, the preset detection cycle may be 500 μs, but is not limited thereto. In another embodiment, the preset detection cycle may also be 400 μs or 600 μs, adjustable according to actual needs.

When both the first detection signal Ds1 and the second detection signal Ds2 are at high level, the AND gate AG generates the first logic signal Ls1 at high level. When either the first detection signal Ds1 or the second detection signal Ds2 is at low level, the AND gate AG generates the first logic signal Ls1 at low level.

When the NOR gate NG does not receive the undervoltage lockout signal Xs from the high-voltage power supply 23 or the brown-out detection signal Bs from the high-voltage power supply 23 for a duration shorter than the warning time interval (e.g., 500 μs, 600 μs, adjustable according to actual needs), both input signals of the NOR gate NG are at low level. At this time, the NOR gate NG generates the second logic signal Ls2 at high level and transmits the second logic signal Ls2 at high level to the latch SL. If the output voltage of the high-voltage power supply 23 is less than 15 V (but not limited thereto; it may also be 16 V, 18 V, etc.), the high-voltage power supply 23 may output the undervoltage lockout signal Xs to indicate that it is in the undervoltage lockout state. If the output voltage of the high-voltage power supply 23 falls below a specific threshold (this threshold may range from 0.5 V to 0.8 V), the brown-out detection signal Bs is generated. If the duration of the brown-out detection signal Bs is greater than or equal to the warning time interval, it indicates that the high-voltage power supply 23 is in the abnormal voltage state. Conversely, if the NOR gate NG receives the undervoltage lockout signal Xs from the high-voltage power supply 23 or the duration of the brown-out detection signal Bs from the high-voltage power supply 23 is greater than or equal to the warning time interval (e.g., 500 μs, 600 μs, adjustable according to actual needs), one of the two input signals of the NOR gate NG is at low level. At this time, the NOR gate NG generates the second logic signal Ls2 at low level and transmits the second logic signal Ls2 at low level to the latch SL.

When both the first logic signal Ls1 and the second logic signal Ls2 are at high level, the latch SL controls the switch driver 12 to turn on the switch element 13 to execute a ballast mode and drive the load. When either the first logic signal Ls1 or the second logic signal Ls2 is at low level, the latch SL does not control the switch driver 12 to turn on the switch element 13.

As described above, through the multiple detection mechanisms, the high-frequency signal recognizer 111’ can ensure via the first timer CT1 that the frequency of the first input signal Is1 is sufficiently high, conforming to the characteristics of a ballast signal rather than noise or other signals. Simultaneously, the high-frequency signal recognizer 111’ can ensure via the second timer CT2 that the voltage of the first input signal Is1 is sufficiently high and stable, and the frequency thereof conforms to the characteristics of a ballast signal rather than noise or other signals. Additionally, the high-frequency signal recognizer 111’ can ensure via the NOR gate NG that the high-voltage power supply 23 is neither in the undervoltage lockout state nor in the abnormal voltage state, conforming to the characteristics of a normal voltage state. Thus, the high-frequency signal recognizer can effectively determine whether the first input signal Is1 is noise or a ballast signal to prevent the power controller 1G from malfunctioning and to appropriately execute the ballast mode.

Moreover, through the multiple detection mechanisms, the high-frequency signal recognizer 111’ can also effectively detect the undervoltage lockout state or abnormal voltage state of the high-voltage power supply 23. This ensures that the power controller 1G operates normally and stably, enhancing the stability thereof.

Furthermore, the power controller 1G further includes the reference voltage generator 14, the current controller 15, the time controller 16, the peak current detector 17, the zero-crossing detector 18, and the impedance identifier 19. The signal identification component 11 also includes the direct-current signal identifier 112 and the power frequency signal identifier 113. Thus, the power controller 1G can execute either a utility power mode or a direct-current power mode through the above components. Consequently, the power controller 1G is compatible with ballasts, utility power, and direct-current power sources (e.g., adapters, batteries) without requiring additional detection circuits, thereby achieving high compatibility. Moreover, the complexity of the driver circuit is reduced, enabling the power controller 1G to achieve miniaturization and lower manufacturing costs

The embodiment just exemplifies the present invention and is not intended to limit the scope of the present invention; any equivalent modification and variation according to the spirit of the present invention is to be also included within the scope of the following claims and their equivalents.

To sum up, according to the embodiments of the present invention, the high-frequency signal recognizer incorporates multiple detection mechanisms. Thus, the high-frequency signal recognizer can ensure, via the first timer, that the frequency of the first input signal is sufficiently high, conforming to the characteristics of a ballast signal rather than noise or other signals. Simultaneously, the high-frequency signal recognizer can ensure, via the second timer, that the voltage of the first input signal is sufficiently high and stable, and the frequency thereof conforms to the characteristics of a ballast signal rather than noise or other signals. Additionally, the high-frequency signal recognizer can ensure, via the NOR gate, that the high-voltage power supply is neither in the undervoltage lockout state nor in the abnormal voltage state, thereby meeting the requirements of normal voltage conditions. In this way, the high-frequency signal recognizer can effectively determine whether the first input signal is noise or a ballast signal, preventing malfunction of the power controller and enabling proper execution of the ballast mode.

Also, according to the embodiments of the present invention, the high-frequency signal recognizer features multiple detection mechanisms. In this way, the high-frequency signal recognizer can also effectively detect the undervoltage lockout state or abnormal voltage state of the high-voltage power supply, which can make sure that the power controller operates normally and stably, thereby enhancing the overall reliability thereof.

Further, according to one embodiment of the present invention, the power controller further includes a reference voltage generator, a current controller, a time controller, a peak current detector, a zero-crossing detector, and an impedance identifier. The signal identification component also includes a direct-current signal identifier and a power frequency signal identifier. Thus, the power controller can execute either a utility power mode or a direct-current power mode through the above components. Consequently, the power controller can be compatible with ballasts, utility power, and direct-current power sources (e.g., adapters, batteries) without requiring additional detection circuits, thereby achieving high compatibility. Moreover, the complexity of the driver circuit is reduced, enabling the power controller to achieve miniaturization and lower manufacturing costs.

Moreover, according to one embodiment of the present invention, the switch element of the power controller may also be an external switch element. The power controller can include a port through which the switch driver connects to the external switch element. Thus, the power controller can be configured with either an integrated switch element or an external switch element, depending on practical requirements, such that the power controller can conform to the requirements of different applications.

Furthermore, according to one embodiment of the present invention, the power controller can achieve the desired functionality through a simple circuit design and operational mechanism. As a result, it not only reduces manufacturing costs but also achieves the intended performance. This significantly enhances the practicality of the power controller, making it more versatile in application and more flexible in use.

It will be apparent to those skilled in the art that various modifications and variations can be made to the disclosed embodiments. It is intended that the specification and examples be considered as exemplary only, with a true scope of the present invention being indicated by the following claims and their equivalents.

What is claimed is:

1. A highly compatible power controller, comprising:
a signal recognition element comprising a high-frequency signal recognizer, wherein the high-frequency signal recognizer comprises a signal input terminal, a signal adjuster, a first timer, a second timer, an AND gate, and a latch;
a switch driver; and
a switch element;
wherein the signal input terminal is configured to receive a first input signal and transmit the first input signal to the signal adjuster, the signal adjuster is configured to generate an adjusted signal based on the first input signal and transmit the adjusted signal to the first timer, the first timer is configured to detect a frequency of the adjusted signal according to a preset detection window and generate a first detection signal, and transmit the first detection signal to the AND gate, the second timer is configured to generate a second detection signal according to the first input signal and a voltage startup threshold, and transmit the second detection signal to the AND gate to cause the AND gate to output a first logic signal to the latch, and the latch is configured to control the switch driver to turn on or turn off the switch element according to the first logic signal.

2. The highly compatible power controller as claimed in claim 1, wherein the high-frequency signal recognizer further comprises a NOR gate, the NOR gate is configured to generate a second logic signal according to an output signal of a high-voltage power supply and transmit the second logic signal to the latch, and the latch is configured to control the switch driver to turn on or turn off the switch element according to the first logic signal and the second logic signal.

3. The highly compatible power controller as claimed in claim 2, wherein the first timer is configured to generate the first detection signal at high level when the first timer determines that a frequency of the adjusted signal is greater than or equal to a frequency threshold, and transmit the first detection signal at high level to the AND gate, the second timer is configured to generate the second detection signal at high level when the first input signal is greater than or equal to the voltage startup threshold and transmit the second detection signal at high level to the AND gate to cause the AND gate to generate the first logic signal at high level, and the NOR gate is configured to generate the second logic signal at high level when the NOR gate does not receive an undervoltage lockout signal from the high-voltage power supply and a duration of a brown-out detection signal from the high-voltage power supply is less than a warning time interval, and transmit the second logic signal at high level to the latch to cause the latch to control the switch driver to turn on the switch element.

4. The highly compatible power controller as claimed in claim 3, wherein the latch does not control the switch driver to turn on the switch element when either the first logic signal or the second logic signal is at low level.

5. The highly compatible power controller as claimed in claim 3, wherein the second timer is configured to receive the voltage startup threshold, compare the first input signal with the voltage startup threshold, and generate the second detection signal at high level when the second timer determines that the first input signal is greater than or equal to the voltage startup threshold, and transmit the second detection signal at high level to the AND gate.

6. The highly compatible power controller as claimed in claim 1, wherein the signal adjuster is configured to receive a reference signal and generate the adjusted signal according to the reference signal and the first input signal, and transmit the adjusted signal to the first timer.

7. The highly compatible power controller as claimed in claim 1, wherein the signal adjuster is an inverter, a comparator, or an operational amplifier.

8. The highly compatible power controller as claimed in claim 1, further comprising a reference voltage generator, a current controller, a time controller, a peak current detector, and a zero-crossing detector, wherein the signal identification element further comprises a direct-current signal identifier connected to the reference voltage generator, wherein the reference voltage generator is connected to the current controller, wherein the current controller is connected to the time controller and the peak current detector, wherein the time controller is connected to the zero-crossing detector, the peak current detector, and the switch driver, wherein the direct-current signal identifier is configured to receive a second input signal and, upon determining that the second input signal is a direct-current signal, output a direct-current identification signal to the reference voltage generator to generate a reference voltage, wherein the current controller is configured to generate a current control signal according to the reference voltage and a peak current detection signal of the peak current detector, wherein the time controller is configured to generate a first pulse-width modulation signal according to the current control signal, the peak current detection signal, and a zero-crossing detection signal of the zero-crossing detector to control the switch driver to control the switch element.

9. The highly compatible power controller as claimed in claim 8, further comprising an impedance identifier, wherein the signal identification element further comprises a power frequency signal identifier connected to the impedance identifier, and the impedance identifier is connected to the reference voltage generator, wherein the power frequency signal identifier is configured to receive a second input signal and, upon determining that the second input signal is a power frequency signal, output a power frequency identification signal to the reference voltage generator to generate the reference voltage, wherein the current controller is configured to generate the current control signal according to the reference voltage and the peak current detection signal, wherein the time controller is configured to generate a second pulse-width modulation signal according to the current control signal, the peak current detection signal, and the zero-crossing detection signal to control the switch driver to control the switch element.

10. The highly compatible power controller as claimed in claim 8, further comprising an overheat protector connected to the reference voltage generator, wherein the overheat protector transmits an overheat protection signal to the reference voltage generator to reduce the reference voltage when overheat protector detects that a temperature exceeds a temperature threshold.
